(19) United States
(12) Patent Application Publication
(10) Pub. No.: US 2019/0363031 A1
(43) Pub. Date: Nov. 28, 2019

(54) MODULE COMPONENT

(71) Applicant: Murata Manufacturing Co., Ltd., Nagaokakyo-shi (JP)

(72) Inventor: Koji KAMADA, Nagaokakyo-shi (JP)

(21) Appl. No.: 16/533,824

(22) Filed: Aug. 7, 2019

Related U.S. Application Data
(63) Continuation of application No. PCT/JP2018/025242, filed on Jul. 3, 2018.

(30) Foreign Application Priority Data
Sep. 7, 2017 (JP) 2017-171824

(51) Int. Cl. H01L 23/31; H01L 23/29; H01L 25/04; H01L 25/18; H05K 9/00; H05K 1/02; H05K 1/18; H05K 1/14; H05K 3/28

(52) U.S. Cl. CPC H01L 23/3121; H01L 23/29; H01L 25/04; H01L 25/18; H05K 2201/10007; H05K 1/0216; H05K 1/181; H05K 1/141; H05K 3/284; H05K 9/00

(57) ABSTRACT

A module component includes a substrate, components mounted to one principal surface of the substrate, a nonmagnetic member covering at least a portion of one or more electrodes different from a ground electrode in each of the mounted components, and a magnetic member covering the one principal surface of the substrate, the mounted components, and the nonmagnetic member.

### CROSS REFERENCE TO RELATED APPLICATIONS

This application claims the benefit of priority to Japanese Patent Application No. 2017-171824 filed on Sep. 7, 2017 and is a Continuation Application of PCT Application No. PCT/JP2018/025242 filed on Jul. 3, 2018. The entire contents of each application are hereby incorporated herein by reference.

### BACKGROUND OF THE INVENTION

### 1. Field of the Invention

The present invention relates to a module component, and more particularly, to a module component including a magnetic member to reduce or prevent radiation of noise to the outside.

### 2. Description of the Related Art

There is known a module component in which to-be-mounted components are mounted to a substrate.

Japanese Unexamined Patent Application Publication No. 8-186978 discloses a module component including a plurality of mounted components that are covered with composite ferrite, which is prepared by mixing ferrite powder into resin, to shield noise emitted from the mounted components by the composite ferrite and to reduce or prevent radiation of the noise to the outside.

However, because the module component disclosed in Japanese Unexamined Patent Application Publication No. 8-186978 encloses the noise emitted from the mounted components within the module component by the composite ferrite, there is a possibility that the noise emitted from any of the mounted components may propagate to one or more other mounted components through the composite ferrite.

### SUMMARY OF THE INVENTION

Preferred embodiments of the present invention provide module components that are each able to reduce or prevent not only radiation of noise to the outside, but also noise propagation between or among a plurality of mounted components mounted to a substrate.

A module component according to a preferred embodiment of the present invention includes a substrate; a plurality of components mounted to one principal surface of the substrate; a nonmagnetic member covering at least a portion of one or more electrodes different from a ground electrode in each of the plurality of mounted components; and a magnetic member covering the one principal surface of the substrate, the plurality of mounted components, and the nonmagnetic member.

The nonmagnetic member may individually cover the plurality of mounted components.

The above module component may further include a metal layer covering the magnetic member, and the metal layer may be connected to a ground.

The ground electrodes of the plurality of mounted components may be covered with the magnetic member.

The nonmagnetic member may further cover a wiring line other than a wiring line connected to a ground.

The plurality of mounted components may include an IC that includes a plurality of electrodes including the ground electrode.

The plurality of mounted components may include an electronic component including one electrode defining and functioning as the ground electrode and another electrode different from the ground electrode, and the ground electrode may be covered with the magnetic member, and the one electrode different from the ground electrode may be covered with the nonmagnetic member.

With the module components according to preferred embodiments of the present invention, since at least a portion of one or more electrodes different from the ground electrode in each of the mounted components mounted to the one principal surface of the substrate is covered with the nonmagnetic member, propagation of noise between or among the mounted components through the magnetic member is able to be reduced or prevented. Furthermore, since the one principal surface of the substrate, the mounted components, and the nonmagnetic member are covered with the magnetic member, radiation of noise to the outside of the module component is able to be reduced or prevented. Thus, module components with less noise and higher reliability are able to be provided.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a schematic plan view of a module component according to a first preferred embodiment of the present invention.

FIG. 2 is a sectional view of the module component according to the first preferred embodiment of the present invention when the module component is sectioned along a line II-II in FIG. 1.

FIG. 3 is an equivalent circuit diagram of the module component illustrated in FIGS. 1 and 2.

FIG. 4 is a sectional view illustrating a positional relationship between a nonmagnetic resin and a magnetic resin when a wiring line connecting mounted components to each other is disposed on a substrate.

FIG. 5 is a sectional view of a module component according to a second preferred embodiment of the present invention.

FIG. 6 is an explanatory view to explain a method of manufacturing the module component according to the second preferred embodiment of the present invention.

FIG. 7 is an explanatory view to explain a method of forming the nonmagnetic resin over portions of the mounted component other than a ground electrode by resin potting.

### DETAILED DESCRIPTION OF THE PREFERRED EMBODIMENTS

Features of the present invention will be described in detail below with reference to preferred embodiments of the present invention and the drawings.

### First Preferred Embodiment

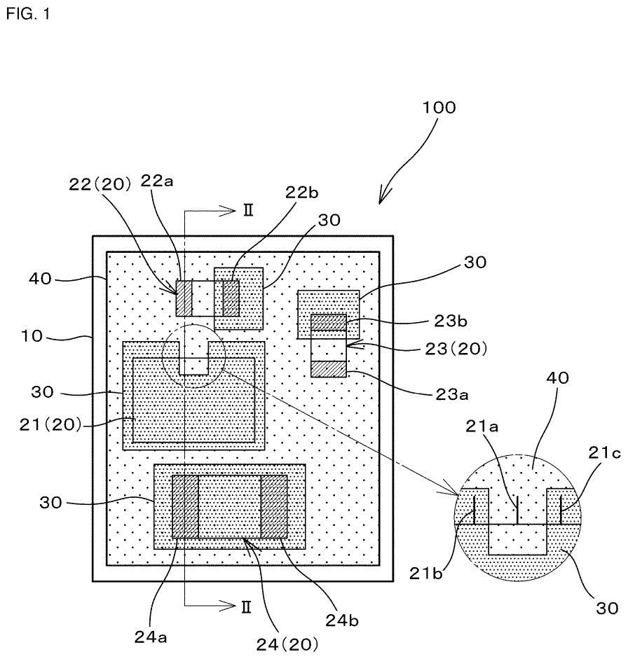

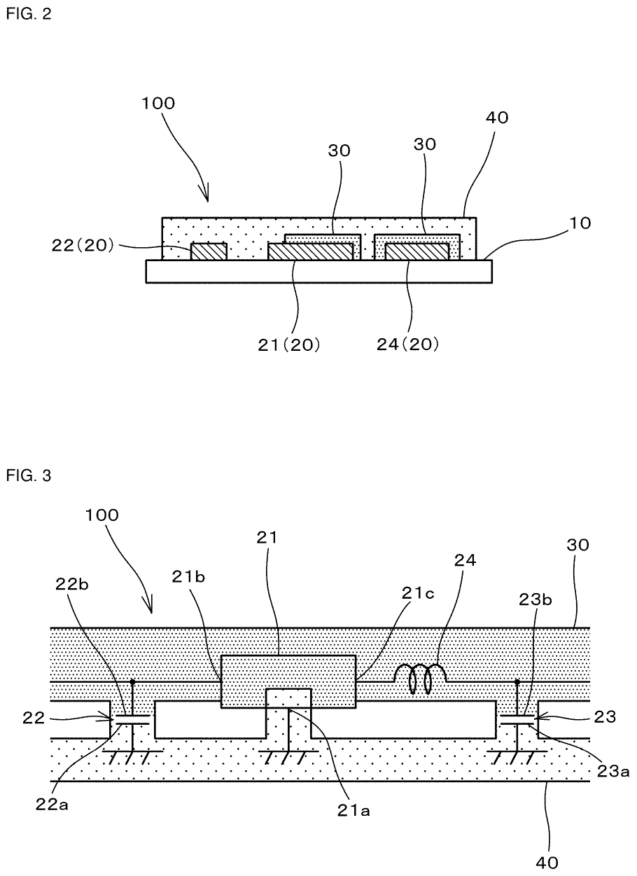

FIG. 1 is a schematic plan view of a module component 100 according to a first preferred embodiment of the present invention. FIG. 2 is a sectional view of the module component 100 when the module component 100 is sectioned along a line II-II in FIG. 1. FIG. 3 is an equivalent circuit diagram of the module component 100 illustrated in FIGS. 1 and 2.

The module component 100 according to the first preferred embodiment includes a substrate 10, a plurality of mounted components 20, a nonmagnetic resin 30 defining a magnetic member, and a magnetic resin 40 defining a magnetic member. The following description is provided on an assumption that the module component 100 preferably defines a DC-DC converter, for example.

The mounted components 20 are mounted to one principal surface of the substrate 10. The mounted components 20 are each an electronic component and preferably include, for example, an IC (integrated circuit), a capacitor, an inductor, a transistor, and the like. The following description is provided on an assumption that an IC 21, an input-side capacitor 22, an output-side capacitor 23, and an inductor 24 are mounted as the mounted components 20 to the substrate 10. It is to be noted that, in FIGS. 1 and 2, wiring lines connected to the mounted components 20 are omitted.

Each of the mounted components 20 includes a ground electrode connected to a ground, and at least one electrode other than the ground electrode. In consideration of the fact that a terminal may be regarded as the same or substantially the same as an electrode in terms of function, even when a member disposed in the mounted component 20 is an element generally referred to a “terminal”, it is described as an “electrode” in this specification.

The electrodes other than the ground electrode are preferably, for example, an input electrode, an output electrode, a control electrode, and the like.

The IC 21 includes three electrodes, i.e., a first terminal electrode 21a, a second terminal electrode 21b, and a third terminal electrode 21c. The first terminal electrode 21a is the ground electrode. The second terminal electrode 21b and the third terminal electrode 21c are the electrodes different from the ground electrode.

The input-side capacitor 22 includes a first outer electrode 22a and a second outer electrode 22b. The first outer electrode 22a is the ground electrode, and the second outer electrode 22b is the electrode different from the ground electrode.

The output-side capacitor 23 includes a third outer electrode 23a and a fourth outer electrode 23b. The third outer electrode 23a is the ground electrode, and the fourth outer electrode 23b is the electrode different from the ground electrode.

The inductor 24 includes a fifth outer electrode 24a and a sixth outer electrode 24b. Because the inductor 24 is not directly connected to the ground, it does not include the ground electrode.

The nonmagnetic resin 30 covers at least a portion of one or more electrodes, different from the ground electrode, of the electrodes in each of the mounted components 20. In order to effectively reduce or prevent noise interference between or among the mounted components 20, however, the nonmagnetic resin 30 preferably covers the entirety or substantially the entirety of one or more electrodes, different from the ground electrode, of the electrodes in each of the mounted components 20.

The nonmagnetic resin 30 may preferably be made of, for example, an epoxy resin containing ferrite powder having a lower permeability than ferrite powder contained in the magnetic resin 40, an epoxy resin containing nonmagnetic ferrite powder, or an epoxy resin containing no magnetic powder such as ferrite powder. In other words, the term “nonmagnetic member” represents not only a perfectly nonmagnetic member, but also a member having a lower permeability than the magnetic member (magnetic resin 40).

Like an LGA (Land Grid Array) package product including electrode pads at a bottom surface, a mounted component is provided in which no electrodes are exposed to a surface when mounted to the substrate 10. When this type of mounted component is mounted to the substrate 10, the nonmagnetic resin 30 covers the mounted component. Even with such a structure, noise generated from the mounted component including the electrodes not exposed to the surface is able to be reduced or prevented from interfering with the other one or more mounted components.

Thus, the nonmagnetic resin 30 may cover portions of each of the mounted components 20 other than the ground electrode.

In the example illustrated in FIGS. 1 and 2, the nonmagnetic resin 30 covers portions of the IC 21 other than the first terminal electrode 21a that is the ground electrode, namely covers the second terminal electrode 21b, the third terminal electrode 21c, and the entirety or substantially the entirety of a body portion of the IC 21.

Furthermore, the nonmagnetic resin 30 individually covers the second outer electrode 22b of the input-side capacitor 22 and the fourth outer electrode 23b of the output-side capacitor 23.

As described above, because the inductor 24 is not directly connected to the ground, it does not include the ground electrode. In the present preferred embodiment, therefore, the nonmagnetic resin 30 covers the entirety or substantially the entirety of the inductor 24, including the fifth outer electrode 24a and the sixth outer electrode 24b.

In the present preferred embodiment, as illustrated in FIG. 1, the nonmagnetic resin 30 is provided individually for each of the mounted components 20. In other words, the nonmagnetic resin 30 individually covers one or more target portions for each of the IC 21, the input-side capacitor 22, the output-side capacitor 23, and the inductor 24.

When wiring lines other than those connected to the ground are disposed on the one principal surface of the substrate 10, the nonmagnetic resin 30 preferably covers each of the wiring lines as well.

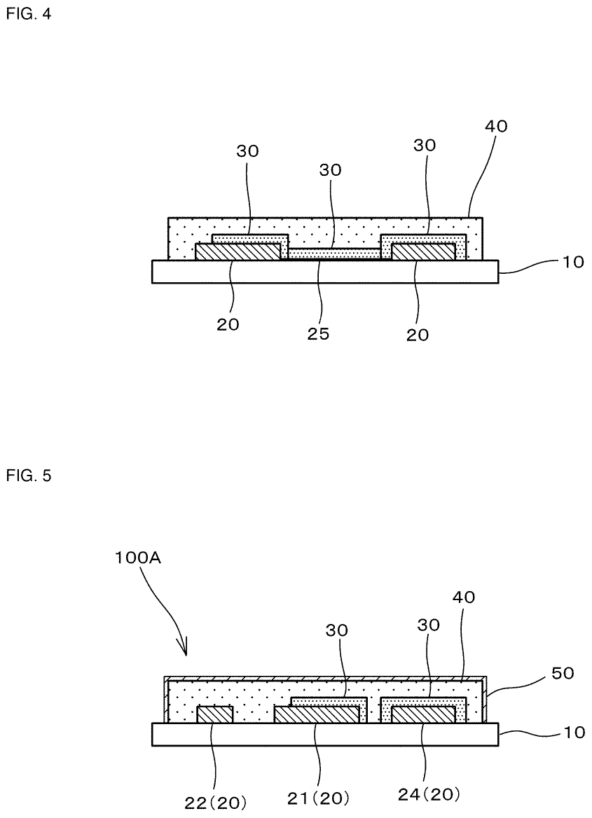

FIG. 4 is a sectional view illustrating a positional relationship between the nonmagnetic resin 30 and the magnetic resin 40 when a wiring line 25 connecting the mounted components 20 to each other is disposed on the one principal surface of the substrate 10. The wiring line 25 is not connected to the ground. In this case, the nonmagnetic resin 30 covers not only at least a portion of one or more electrodes, different from the ground electrode, of the electrodes in each of the mounted components 20, but also the wiring line 25.

The magnetic resin 40 covers the one principal surface of the substrate 10, the mounted components 20, and the nonmagnetic resin 30. However, the one principal surface of the substrate 10 is not always required to be entirely or substantially entirely covered with the magnetic resin 40. The magnetic resin 40 preferably covers at least a region of the substrate 10 where the mounted components 20 are mounted.

The magnetic resin 40 is preferably a resin having a higher permeability than the nonmagnetic resin 30, and it may be prepared, for example, by mixing ferrite powder into an epoxy resin.

As described above, the nonmagnetic resin 30 covers at least a portion of one or more electrodes, different from the ground electrode, of the electrodes in each of the mounted components 20. This implies that the magnetic resin 40 covers the ground electrode in each of the mounted components 20. In the example illustrated in FIGS. 1 and 2, the magnetic resin 40 covers the first terminal electrode 21a that is the ground electrode of the IC 21, the first outer electrode 22a that is the ground electrode of the input-side capacitor 22, and the third outer electrode 23a that is the ground electrode of the output-side capacitor 23.

With the magnetic resin 40 covering the ground electrode of each of the mounted components 20, noise emitted from the mounted components 20 is easily input to the ground, and radiation of the noise to the outside of the module component 100 is able to be effectively reduced or prevented.

In the module component 100 according to the present preferred embodiment, since the magnetic resin 40 covers the one principal surface of the substrate 10, the mounted components 20, and the nonmagnetic resin 30, the noise emitted from the mounted components 20 is able to be reduced or prevented from being radiated to the outside of the module component 100.

Stated in another way, in the module component 100, the magnetic resin 40 encloses the noise within the module component 100, and reduces or prevents the radiation of the noise to the outside.

In the module component 100 according to the present preferred embodiment, the nonmagnetic resin 30 covers at least a portion of one or more electrodes, different from the ground electrode, of the electrodes in each of the mounted components 20 in order to avoid the noise enclosed within the module component 100 from interfering with the other one or more mounted components 20. Because a large portion of the noise propagates in the magnetic resin, the above-described structure is able to reduce or prevent the noise emitted from any of the mounted components 20 from propagating to the other one or more mounted components 20 through the magnetic resin 40.

Furthermore, the nonmagnetic resin 30 individually covers at least a portion of one or more electrodes, different from the ground electrode, of the electrodes for each of the mounted components 20. Thus, the magnetic resin 40 is positioned between the electrodes disposed adjacent to each other or nearby, and the noise is concentrated in the magnetic resin 40. It is thus possible to effectively reduce or prevent the occurrence of noise interference between the electrodes that are different from the ground electrode and that are disposed adjacent to each other or nearby.

Moreover, since the ground electrode in each of the mounted components 20 is covered with the magnetic resin 40, the noise emitted from each of the mounted components 20 is easily input to the ground, and radiation of the noise to the outside of the module component 100 and to the other one or more mounted components 20 is able to be effectively reduced or prevented.

In addition, in the case of wiring lines being disposed on the one principal surface of the substrate 10, since the nonmagnetic resin 30 further covers one or more of the wiring lines other than that or those connected to the ground, the noise emitted from the mounted components 20 is able to be reduced or prevented from being input to the other wiring lines. As a result, propagation of the noise to the other mounted components 20 through the wiring lines is able to be reduced or prevented.

### Second Preferred Embodiment

FIG. 5 is a sectional view of a module component 100A according to a second preferred embodiment of the present invention. The module component 100A according to the second preferred embodiment further includes a metal layer 50 covering the magnetic resin 40 in addition to the structure of the module component 100 according to the first preferred embodiment. The metal layer 50 defines and functions as a metal shield covering the outer exposed side of the module component.

The metal layer 50 is preferably made of, for example, aluminum or copper. The metal layer 50 is connected to the ground and is not in contact with the nonmagnetic resin 30.

By including the metal layer 50 covering the magnetic resin 40, the module component 100A according to the second preferred embodiment is able to effectively reduce or prevent radio frequency noise.

Furthermore, since the metal layer 50 is connected to the ground and is not in contact with the nonmagnetic resin 30, noise propagating from the metal layer 50 to the ground is able to be reduced or prevented from propagating to the mounted component 20 through the nonmagnetic resin 30.

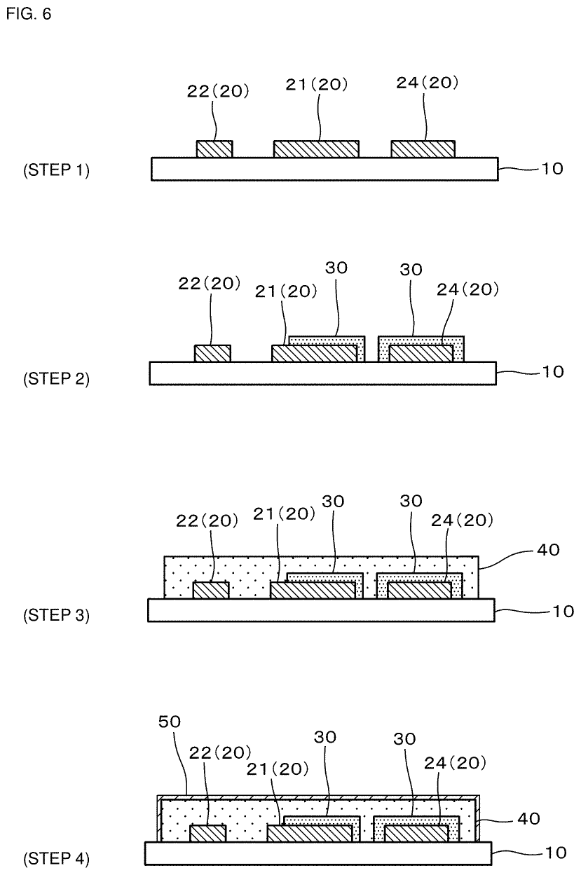

A non-limiting example of a method of manufacturing the module component 100A according to the second preferred embodiment will be described below with reference to FIG. 6.

In step 1, the mounted components 20, i.e., the IC 21, the input-side capacitor 22, the output-side capacitor 23, and the inductor 24, are mounted to the one principal surface of the substrate 10. The type of the substrate 10 is not particularly limited. For example, a resin substrate or a ceramic substrate may preferably be used as the substrate 10.

In step 2, the nonmagnetic resin 30 is disposed to cover at least a portion of one or more electrodes, different from the ground electrode, of the electrodes in each of the mounted components 20.

The nonmagnetic resin 30 is preferably formed by resin potting, for example. A method of forming the nonmagnetic resin 30 over a portion of one mounted component 20 other than the ground electrode by the resin potting is described here.

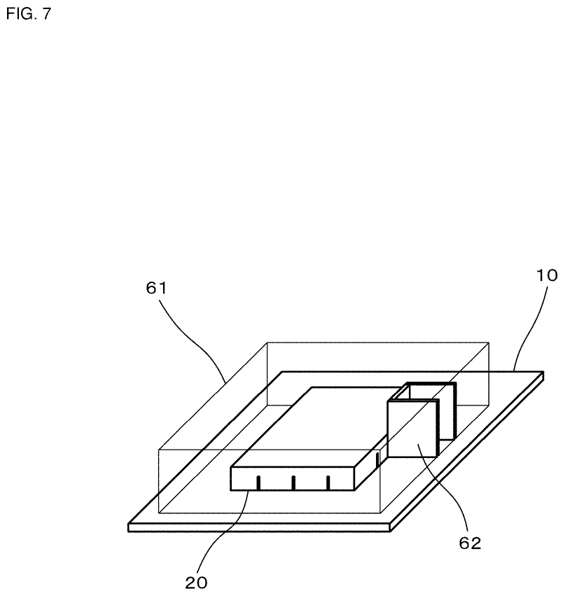

As illustrated in FIG. 7, a partition 61 for the resin potting is disposed to surround a periphery of the mounted component 20, and a partial partition 62 having a C-shape or substantially C-shape in plan is disposed to prevent the ground electrode of the mounted component 20 from being covered with the nonmagnetic resin 30. It is to be noted that FIG. 7 illustrates only a portion of the substrate 10.

The ground electrode is disposed, though not illustrated in FIG. 7, at a position locating on a lateral surface of the mounted component 20 and is contiguous to the partial partition 62. Additionally, in FIG. 7, the partition 61 is illustrated as being transparent to facilitate understanding.

Then, a nonmagnetic resin is injected into a region surrounded by the partition 61. At that time, the nonmagnetic resin is avoided from being injected into a region surrounded by the partial partition 62. The injected nonmagnetic resin is then solidified. Thus, the nonmagnetic resin 30 is formed. After the nonmagnetic resin 30 has been formed, the partition 61 and the partial partition 62 are removed.

In step 3, the magnetic resin 40 is disposed to cover the one principal surface of the substrate 10, the mounted components 20, and the nonmagnetic resin 30. The magnetic resin 40 may preferably be formed by resin potting, for example, as in the above-described step 2 of forming the nonmagnetic resin 30.

Solidification of the nonmagnetic resin in step 2 and solidification of the magnetic resin in step 3 may be performed at the same time.

In step 4, the metal layer 50 is formed on a surface of the magnetic resin 40. The metal layer 50 may be formed, for example, by a sputtering method, or by covering a metal case over the magnetic resin 40.

Through the above-described steps 1 to 4, the module component 100A according to the second preferred embodiment may be manufactured. In the case of manufacturing the module component 100 according to the first preferred embodiment, the above-described step 4 is not needed.

The present invention is not limited to the above-described preferred embodiments and may be variously improved and modified within the scope of the present invention. For instance, while, in the above-described preferred embodiments, the module component 100 has been described as a component used in a DC-DC converter, the module component is not limited to the component used in a DC-DC converter. In other words, the type, number, layout, and the like of the mounted components 20 mounted to the substrate 10 are not limited to those described in the above preferred embodiments.

In the above-described preferred embodiments, as illustrated in FIG. 1, the nonmagnetic resin 30 individually covers at least a portion of each of the mounted components 20. However, when the adjacent mounted components 20 are positioned close to each other, the nonmagnetic resin 30 may cover target portions of those mounted components 20 together. In another example, the nonmagnetic resin 30 may cover target portions of all of the mounted components 20 mounted to the substrate 10 together in such a state that the ground electrodes of the mounted components and the surroundings thereof are exposed from the nonmagnetic resin 30.

The nonmagnetic member covering at least a portion of one or more electrodes, different from the ground electrode, of the electrodes in each of the mounted components 20 is not limited to the nonmagnetic resin. The nonmagnetic member may be air, for example.

Moreover, the magnetic member covering the one principal surface of the substrate 10, the mounted components 20, and the nonmagnetic member is not limited to the magnetic resin.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A module component comprising:
a substrate;
a plurality of mounted components that are mounted to one principal surface of the substrate;
a nonmagnetic member covering at least a portion of one or more electrodes different from a ground electrode in each of the plurality of mounted components; and
a magnetic member covering the one principal surface of the substrate, the plurality of mounted components, and the nonmagnetic member.

2. The module component according to claim 1, wherein the nonmagnetic member individually covers the plurality of mounted components.

3. The module component according to claim 1, further comprising:
a metal layer covering the magnetic member; wherein
the metal layer is connected to a ground.

4. The module component according to claim 1, wherein the ground electrodes of the plurality of mounted components are covered with the magnetic member.

5. The module component according to claim 1, wherein the nonmagnetic member further covers a wiring line other than a wiring line connected to a ground.

6. The module component according to claim 1, wherein the plurality of mounted components include an integrated circuit that includes a plurality of electrodes including the ground electrode.

7. The module component according to claim 1, wherein
the plurality of mounted components include an electronic component including one electrode defining and functioning as the ground electrode and another electrode different from the ground electrode; and
the ground electrode is covered with the magnetic member, and the one electrode different from the ground electrode is covered with the nonmagnetic member.

8. The module component according to claim 1, wherein the plurality of mounted components include at least two of an integrated circuit, a capacitor, an inductor, and a transistor.

9. The module component according to claim 1, wherein the nonmagnetic member covers an entirety or substantially an entirety of the one or more electrodes different from the ground electrode in each of the plurality of mounted components.

10. The module component according to claim 1, wherein the nonmagnetic member is made of one of an epoxy resin containing ferrite powder having a lower permeability than ferrite powder contained in the magnetic resin, an epoxy resin containing nonmagnetic ferrite powder, or an epoxy resin containing no magnetic powder.

11. The module component according to claim 5, wherein the wiring line is disposed on the one principal surface of the substrate.

12. The module component according to claim 1, wherein the magnetic member entirely or substantially entirely covers the one principal surface of the substrate.

13. The module component according to claim 1, wherein the magnetic member is made of a resin having a higher permeability than the nonmagnetic member.

14. The module component according to claim 1, wherein the magnetic member covers the ground electrode of each of the plurality of mounted components.

15. The module component according to claim 3, wherein the metal layer is made of aluminum or cooper.

16. The module component according to claim 3, wherein the metal layer is not in contact with the nonmagnetic members.
